(19) United States
(12) Patent Application Publication
(10) Pub. No.: US 2013/0192761 A1
(43) Pub. Date: Aug. 1, 2013

(54) Rotary Substrate Processing System

(71) Applicants: Joseph Yudovsky, Campbell, CA (US); Ralf Hofmann, Soquel, CA (US); Jeonghoon Oh, San Jose, CA (US); Li-Qun Xia, Cupertino, CA (US); Toshiaki Fujita, Sakura City (JP); Pravin K. Narwankar, Sunnyvale, CA (US); Nag B, Patibandla, Pleasanton, CA (US); Srinivas Satya, Sunnyvale, CA (US); Banqiu Wu, Sunnyvale, CA (US)

(72) Inventors: Joseph Yudovsky, Campbell, CA (US); Ralf Hofmann, Soquel, CA (US); Jeonghoon Oh, San Jose, CA (US); Li-Qun Xia, Cupertino, CA (US); Toshiaki Fujita, Sakura City (JP); Pravin K. Narwankar, Sunnyvale, CA (US); Nag B, Patibandla, Pleasanton, CA (US); Srinivas Satya, Sunnyvale, CA (US); Banqiu Wu, Sunnyvale, CA (US)

(21) Appl. No.: 13/754,733

(22) Filed: Jan. 30, 2013

Related U.S. Application Data
(60) Provisional application No. 61/593,224, filed on Jan. 31, 2012.

(51) Int. Cl. C23C 16/54; B05C 13/00

(52) U.S. Cl. CPC C23C 16/54; B05C 13/00
USPC 156/345.55; 118/719

(57) ABSTRACT

A substrate processing system for processing multiple substrates is provided and generally includes at least one processing platform and at least one staging platform. Each substrate is positioned on a substrate carrier disposed on a substrate support assembly. Multiple substrate carriers, each is configured to carry a substrate thereon, are positioned on the surface of the substrate support assembly. The processing platform and the staging platform, each includes a separate substrate support assembly, which can be rotated by a separate rotary track mechanism. Each rotary track mechanism is capable of supporting the substrate support assembly and continuously rotating multiple substrates carried by the substrate carriers and disposed on the substrate support assembly. Each substrate is thus processed through at least one shower head station and at least one buffer station, which are positioned at a distance above the rotary track mechanism of the processing platform. Each substrate can be transferred between the processing platform and the staging platform and in and out the substrate processing system.

### CROSS-REFERENCE TO RELATED APPLICATIONS

This application claims priority to U.S. Provisional Application No. 61/593,224, filed Jan. 31, 2012.

### BACKGROUND

Embodiments of the present invention generally relate to an apparatus for processing substrates. More particularly, the invention relates to a batch processing platform for performing atomic layer deposition (ALD) and chemical vapor deposition (CVD) on substrates.

The process of forming semiconductor devices is commonly conducted in substrate processing platforms containing multiple chambers. In some instances, the purpose of a multi-chamber processing platform or cluster tool is to perform two or more processes on a substrate sequentially in a controlled environment. In other instances, however, a multiple chamber processing platform may only perform a single processing step on substrates; the additional chambers are intended to maximize the rate at which substrates are processed by the platform. In the latter case, the process performed on substrates is typically a batch process, wherein a relatively large number of substrates, e.g. 25 or 50, are processed in a given chamber simultaneously. Batch processing is especially beneficial for processes that are too time-consuming to be performed on individual substrates in an economically viable manner, such as for ALD processes and some chemical vapor deposition (CVD) processes.

The effectiveness of a substrate processing platform, or system, is often quantified by cost of ownership (COO). The COO, while influenced by many factors, is largely affected by the system footprint, i.e., the total floor space required to operate the system in a fabrication plant, and system throughput, i.e., the number of substrates processed per hour. Footprint typically includes access areas adjacent the system that are required for maintenance. Hence, although a substrate processing platform may be relatively small, if it requires access from all sides for operation and maintenance, the system's effective footprint may still be prohibitively large.

The semiconductor industry's tolerance for process variability continues to decrease as the size of semiconductor devices shrink. To meet these tighter process requirements, the industry has developed a host of new processes which meet the tighter process window requirements, but these processes often take a longer time to complete. For example, for forming a copper diffusion barrier layer conformally onto the surface of a high aspect ratio, 65 nm or smaller interconnect feature, it may be necessary to use an ALD process. ALD is a variant of CVD that demonstrates superior step coverage compared to CVD. ALD is based upon atomic layer epitaxy (ALE) that was originally employed to fabricate electroluminescent displays. ALD employs chemisorption to deposit a saturated monolayer of reactive precursor molecules on a substrate surface. This is achieved by cyclically alternating the pulsing of appropriate reactive precursors into a deposition chamber. Each injection of a reactive precursor is typically separated by an inert gas purge to provide a new atomic layer to previous deposited layers to form an uniform material layer on the surface of a substrate. Cycles of reactive precursor and inert purge gases are repeated to form the material layer to a desired thickness. The biggest drawback with ALD techniques is that the deposition rate is much lower than typical CVD techniques by at least an order of magnitude. For example, some ALD processes can require a chamber processing time from about 10 to about 200 minutes to deposit a high quality layer on the surface of the substrate. In choosing such ALD and epitaxy processes for better device performance, the cost to fabricate devices in a conventional single substrate processing chamber would increase due to very low substrate processing throughput. Hence, when implementing such processes, a continuous substrate processing approach is needed to be economically feasible.

Therefore, a continuous substrate processing approach is needed to save time and improve the quality of the deposited film.

### SUMMARY

Embodiments of the invention provide a substrate processing system to continuously process multiple substrates and improve processing throughput. In one or more embodiments, the substrate processing system comprises a rotary substrate processing platform for processing a plurality of substrates. The rotary substrate processing platform may include one or more gas distribution assemblies and a rotary track mechanism, which is positioned at a first distance below the one or more gas distribution assemblies and is capable of receiving a plurality of substrate carriers. Each substrate carrier is adapted to carry at least one substrate thereon and to be rotationally moved by the rotary track mechanism at a first rotating speed such that the plurality of substrates disposed on the plurality of substrate carriers are rotated under and passed through the one or more gas distribution assemblies. Alternatively, the rotary substrate processing platform may include a rotary substrate support assembly disposed below one or more gas distribution assemblies. The rotary substrate support assembly is adapted to receive and support a plurality of substrates disposed thereon directly or via substrate carriers.

In another embodiment, a substrate processing system is provided and includes a staging platform and a processing platform. The staging platform includes a first rotary track mechanism, capable of receiving a plurality of substrates carriers thereon and/or a plurality of substrates directly. Each substrate carrier is adapted to carry at least one substrate thereon and to be rotationally moved by the first rotary track mechanism at a first rotating speed. The processing platform includes one or more gas distribution assemblies and a second rotary track mechanism. The second rotary track mechanism is positioned at a distance below the one or more gas distribution assemblies and capable of receiving the plurality of substrates directly or the substrates disposed on the substrate carriers for rotationally moving the plurality of the substrates or the substrate carriers at a second rotating speed such that the plurality of the substrates disposed thereon are rotated under and passed through the one or more gas distribution assemblies.

In still another embodiment, a substrate processing system having a substrate processing platform and a staging platform is provided. The staging platform includes a first rotary substrate support assembly having a first multi- substrate receiving surface capable of receiving multiple substrates thereon, and a first rotary actuation mechanism disposed below the first rotary substrate support assembly for rotating the first rotary substrate support assembly at a first rotating speed. The processing platform includes a second rotary substrate support assembly having a second multi-substrate receiving surface capable of receiving the plurality of the substrates thereon, one or more gas distribution assemblies disposed at a first distance above the second substrate support assembly, and a second rotary actuation mechanism disposed below the second rotary substrate support assembly and capable of rotationally moving the second rotary substrate support assembly at a second rotating speed such that the plurality of substrates disposed on the second substrate receiving surface are passed under the one or more gas distribution assemblies.

Methods for processing substrates in such substrate processing system are also provided. One method includes loading a substrate onto a substrate carrier being rotated by a first rotary track mechanism of a staging platform of the substrate processing system, rotating the first rotary track mechanism at a first rotating speed, loading the substrate carrier having the substrate thereon onto a second rotary track mechanism of a processing platform of the substrate processing system, rotating the second rotary track mechanism at a second rotating speed such that the substrate is moved under and passed through one or more gas distribution assemblies positioned at a first distance above the second rotary track mechanism, and unloading the substrate carrier from the second rotary track mechanism onto the first rotary track mechanism of the batch processing platform.

Another method for processing a substrate within a substrate processing system includes loading the substrate onto a first substrate support assembly, which is being rotated by a first rotary track mechanism disposed within a staging platform of the substrate processing system, rotating the first rotary track mechanism at a first rotating speed, loading the substrate carrier having the substrate thereon onto a second substrate support assembly, which is being rotated by a second rotary track mechanism disposed within a processing platform of the substrate processing system, rotating the second rotary track mechanism at a second rotating speed such that the substrate is moved under and passed through one or more gas distribution assemblies positioned at a first distance above the second rotary track mechanism, and unloading the substrate carrier from the second substrate support assembly, of the processing platform onto the first substrate support assembly of the staging platform.

Additional embodiments of the invention are directed to processing chambers comprising a plurality of gas distribution assemblies, a substrate support apparatus and a set of first treatment stations. The plurality of gas distribution assemblies are spaced about the processing chamber. The substrate support apparatus is within the processing chamber. The substrate support apparatus rotates to carry substrates beneath each of the plurality of gas distribution assemblies. The set of first treatment stations is between each of the plurality of gas distribution assemblies and each of the first treatment stations provides the same type of treatment.

In some embodiments, each of the first treatment stations comprises a plasma treatment station. In some embodiments, each of the gas distribution assemblies sequentially provides a first reactive gas and second reactive gas to a substrate surface to deposit a film on the substrate surface. In some embodiments, the substrate support apparatus comprises a plurality of rotatable substrate carriers, the rotatable substrate carriers rotatable at a different speed and directions from the rotation of the substrate support apparatus.

One or more embodiments further comprises a set of second treatment stations. Each of the second treatment stations is positioned between a gas distribution assembly and a first treatment station, so a first treatment station is between a gas distribution assembly and a second treatment station and a second treatment station is between a first treatment station and an adjacent gas distribution assembly.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic plan view of a substrate processing system with four gas distribution assemblies and four intermediate treatment stations in accordance with one or more embodiment of the invention;

FIGS. 2A through 2C are schematic plan views of cluster tools with substrate processing systems having various numbers of gas distribution assemblies;

FIGS. 3 shows a schematic plan view of a substrate processing system including three processing groups, each processing group including a gas distribution assembly, a first treatment station and a second treatment station;

FIG. 4 is a schematic plan view of a substrate processing system configured with two platforms and capable of continuously loading, unloading and processing multiple substrates, each platform with a rotary track mechanism disposed therein, in accordance with one or more embodiments of the invention;

FIG. 4B is a schematic plan view of a substrate processing system configured with two platforms and capable of continuously loading, unloading and processing multiple substrates, each platform with a rotary substrate support assembly disposed therein, in accordance with another embodiment of the invention;

FIG. 5 is a schematic plan view of a processing platform with multiple shower head stations and multiple buffer stations and illustrates a plurality of substrates being rotationally disposed below the gas distribution assemblies of the multiple shower head stations in accordance with one or more embodiments of the invention;

FIG. 6 is a side view of a gas distribution assembly in a shower head station, illustrating the side facing the surface of the substrate and having multiple open gas channels in accordance with one or more embodiments of the invention;

FIG. 7 is a partial cross-sectional side view of a gas distribution assembly in a processing station with the substrate disposed below in accordance with one or more embodiments of the invention; and

FIG. 8 is a partial cross-sectional side view of a processing platform, showing two substrates disposed below two gas distribution assemblies of two processing stations on the surface of a rotary substrate support assembly.

### DETAILED DESCRIPTION

Embodiments of the invention provide a substrate processing system for continuous substrate deposition to maximize throughput and improve processing efficiency. The substrate processing system can also be used for pre-deposition and post-deposition substrate treatments.

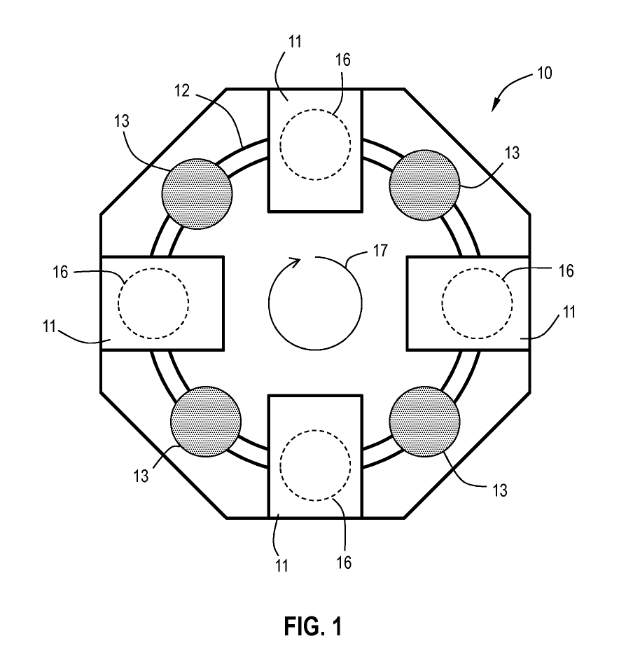

Processing chambers having multiple gas injectors can be used to process multiple wafers simultaneously so that the wafers experience the same process flow. As used in this specification and the appended claims, the terms “substrate” and “wafer” are used interchangeably to refer to a discrete, rigid material upon which processing (e.g., deposition, annealing, etching) is performed. For example, as shown in FIG. 1, the processing chamber has four gas injectors and four wafers. At the outset of processing he wafers can be positioned between the injectors. Rotating the carousel 45° will result in each wafer being moved to an injector for film deposition. An additional 45° rotation would move the wafers away from the injectors. With spatial ALD injectors, a film is deposited on the wafer primarily during movement of the wafer relative to the injector.

The processing chamber 10 shown in FIG. 1 is merely representative of one possible configuration and should not be taken as limiting the scope of the invention. Here, the processing chamber 10 includes a plurality of gas distribution assemblies 11. In the embodiment shown, there are four gas distribution assemblies 11 evenly spaced about the processing chamber 10. The processing chamber 10 shown is octagonal, however, it will be understood by those skilled in the art that this is one possible shape and should not be taken as limiting the scope of the invention.

The processing chamber 10 includes a substrate support apparatus 12 within the processing chamber 10. The substrate support apparatus 12 is capable of moving a plurality of substrates beneath each of the gas distribution assemblies 11. A load lock, not shown, might be connected to a side of the processing chamber 10 to allow the substrates to be loaded/unloaded from the chamber.

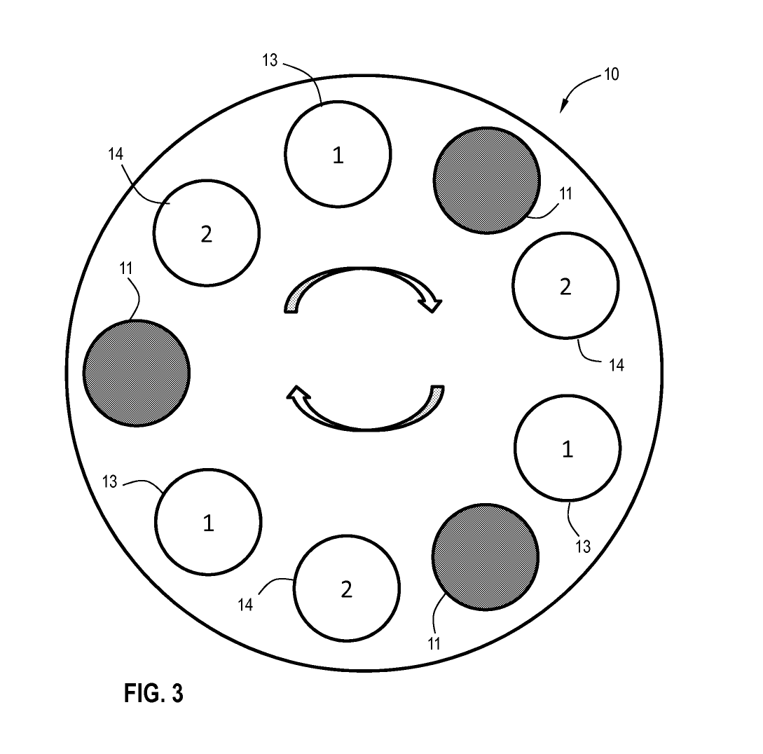

The processing chamber 10 includes a plurality, or set, of first treatment stations 13 positioned between each of the plurality of gas distribution assemblies 11. Each of the first treatment stations 13 provides the same treatment to a substrate. In some embodiments, as shown in FIG. 3, a set of second treatment stations 14 are positioned between the first treatment stations 13 and the gas distribution assemblies 11 so that a substrate rotated through the processing chamber 10 would encounter, depending on where the substrate starts, a gas distribution assembly 11, a first treatment station 13 and a second treatment station 14 before encountering a second of any of these. For example, as shown in FIG. 3, if the substrate started at the first treatment station 13, it would see, in order, the first treatment station 13, a gas distribution assembly 11 and a second treatment station 14 before encountering a second first treatment station 13.

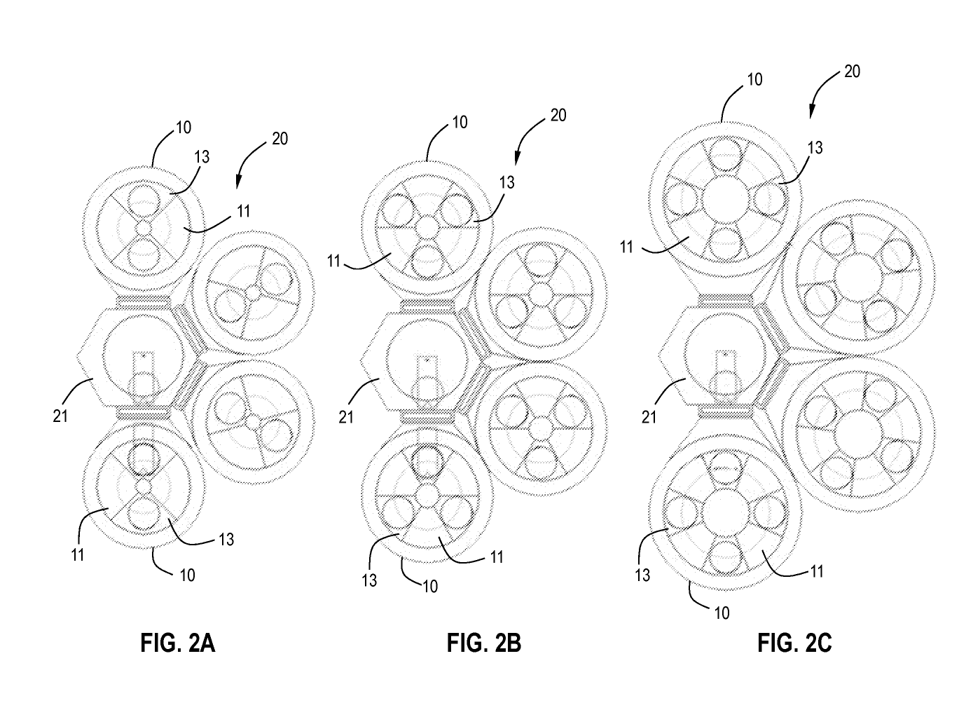

FIGS. 2A through 2C show different embodiments of cluster tools 20 with multiple carousel type processing chamber 10. The embodiment shown in FIG. 2A has four processing chambers 10 around a central transfer station 21. Each of the processing chambers 10 includes two gas distribution assemblies 11 and two first treatment stations 13. The embodiment of FIG. 2B has three gas distribution assemblies 11 and three first treatment stations 13 and the embodiments of FIG. 2C has four gas distribution assemblies 11 and four first treatments stations 13. Other numbers of injectors, or gas distribution assemblies, can be employed as well. In some embodiments, the number of injectors is equal to the number of wafers that can be processed simultaneously. Each wafer is either under the injector or in the region between the injectors so that each wafer has the same experience (i.e., experiences the same conditions) during processing.

Additional processing apparatus can also be positioned between the injectors. For example, US lamps, flash lamps, plasma sources and heaters. The wafers are then moved between positions with the injectors to a position with, for example, a showerhead delivering a plasma to the wafer. In one or more example, silicon nitride films can be formed with plasma treatment after each deposition layer. As the ALD reaction is, theoretically, self-limiting as long as the surface is saturated, additional exposure to the deposition gas will not cause damage to the film.

Rotation of the carousel can be continuous or discontinuous. In continuous processing, the wafers are constantly rotating so that they are exposed to each of the injectors in turn. In discontinuous processing, the wafers can be moved to the injector region and stopped, and then to the region between the injectors and stopped. For example, the carousel can rotate so that the wafers move from an inter-injector region across the injector (or stop adjacent the injector) and on to the next inter-injector region where it can pause again. Pausing between the injectors may provide time for additional processing steps between each layer deposition (e.g., exposure to plasma).

In some embodiments, there are a different number of wafers than injectors maintaining a symmetrical orientation. For example, a processing chamber can have three injectors and six wafers. Initially, none of the wafers are positioned under the injectors; rotation of the carousel 30° would place the first set of wafers under the injectors and move the second set of wafers into a position immediately preceding the injector. The next 30° rotation would move the first set of wafers out from under the injectors and the second set of wafers to the injector region. Again, the substrates can be exposed to additional processing steps between each injector.

The injectors can be substantially parallel (e.g., rectangular shaped) or wedge shaped. Once the surface reactions are saturated, it does not matter if the wafer spends additional time adjacent the injector as no additional reaction will occur.

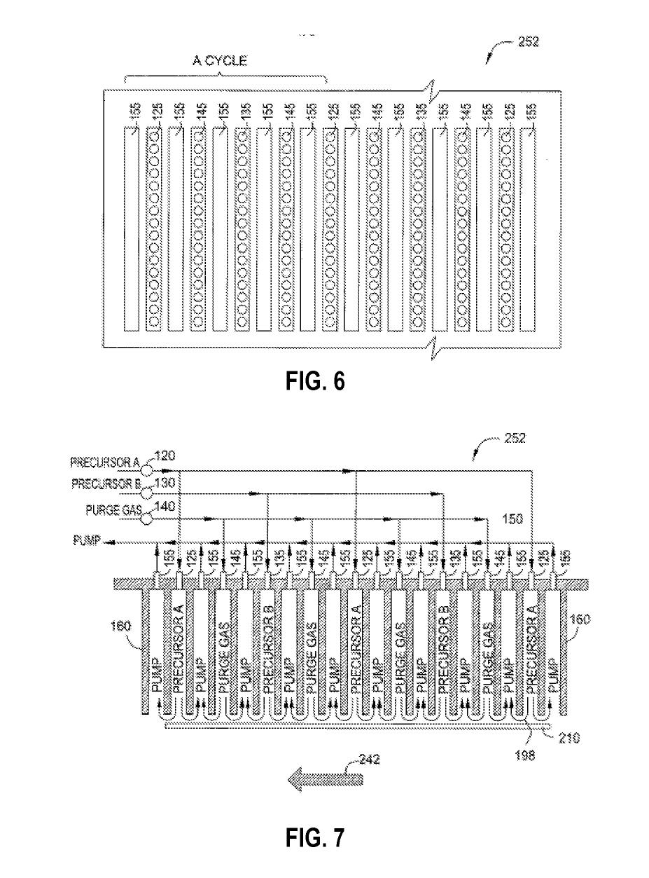

Referring to FIG. 1, one or more embodiments of the invention are directed to methods of processing a plurality of substrates. Each of the plurality of substrates 16 is loaded into the processing chamber 10 so that each substrate 16 is in an relatively identical position as the other substrates 16. As used in this specification and the appended claims, the term “relatively identical”, “relatively the same”, “substantially equal starting positions” and the like, mean that the substrates are in equivalent positions (e.g., each under a gas distribution assembly or each between gas distribution assemblies). For example, each substrate 16 in FIG. 1 is shown positioned under the gas distribution assembly 11. Therefore, each substrate 16 has substantially equal starting positions as the other substrates. The plurality of substrates are positioned on a substrate support apparatus 12 which may include a track portion and/or support structures. The substrate support apparatus 12 rotates the substrates 16 around in a circle 17, or similar shape. Upon rotation, the substrates 16 move from their initial position to a next position which may be under the first treatment stations 13. When the gas distribution assemblies 11 are spatial atomic layer deposition apparatus, like that shown and described in FIG. 7, the movement under the gas distribution assembly causes each portion of the substrate to be exposed to a series of process gases (also referred to as precursor gases or reactive gases, and the like) to deposit a layer on the substrate surface. The substrate then moves to the first treatment station 13 where it is subjected to a post-deposition process. In some embodiments, the post-deposition process is one or more of annealing and plasma treatment.

The substrates are moves either in a continuous uninterrupted manner or in discrete steps. When moved in discrete steps, the substrates may be moved from a first treatment station through the gas distribution assembly area to another first treatment station. This allows the movement of the substrate to cause the sequential exposure of the different reaction gases adjacent the gas distribution assembly to deposit the film.

In some embodiments, alternating gas distribution assemblies provide alternate reaction gases and the alternating first treatment stations provide a different treatment. For example, the first gas distribution assembly may supply a first reactive gas to the substrate surface to form a partial film on the surface, the substrate can then move to a first treatment station where the partial film is heated and then moved to the second gas distribution assembly where a second reactive gas reacts with the partial film to form a complete film followed by moving the substrate to another first treatment station where the film is exposed to a plasma to, for example, densify the film.

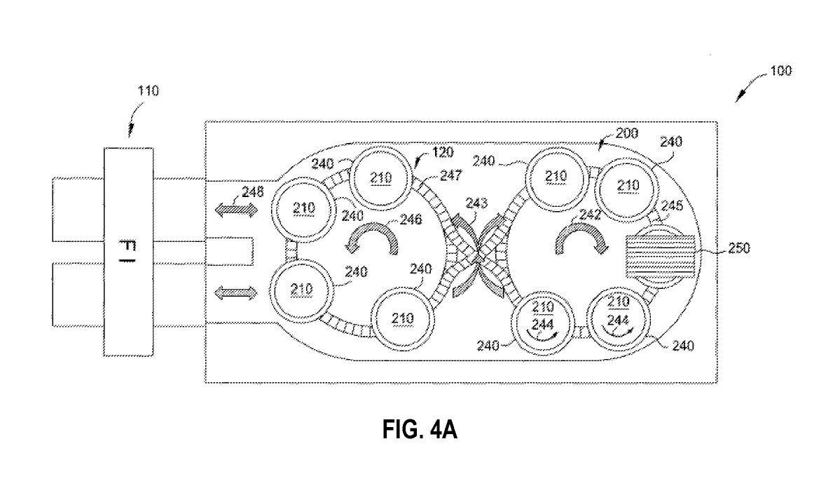

FIG. 4A is a schematic plan view of a substrate processing system 100 for continuous, multiple substrates processing. The substrate processing system 100 may include a staging platform 120 and a processing platform 200, connected to the staging platform 120. The processing platform 200 can be used for depositing a material layer over a plurality of substrates 210 in an ALD or CVD process. Optionally, the substrate processing system 100 includes a factory interface 110. The substrates 210 may be transferred (e.g., one substrate at a time or two substrates transferred in tandem as shown in FIG. 4A) in a direction 248 from the factory interface 110 and loaded onto the staging platform 120. In general, a low contamination clean environment is maintained within the substrate processing system 100.

In one or more embodiments, throughput is improved by using rotary mechanisms. A plurality of the substrates 210 can be disposed directly on the rotary track mechanisms and being rotated and continuously processed inside the substrate processing system 100. Alternatively, the rotary track mechanisms 245, 247 may be configured to receive a plurality of substrate carriers 240 such that the substrates 210 are disposed on the substrate carriers 240 and moved around the processing system 100). In one or more embodiments, each substrate carrier 240 disposed on the rotary track mechanism is capable of self-rotating at a second rotating speed and carrying a substrate 210 thereon.

For example, the staging platform 120 may include a first rotary track mechanism 247 to support and rotate a plurality of the substrates 210 in a direction 246 (e.g., clockwise or counterclockwise) and at a first rotating speed (e.g., from zero to less than 30 rpm). The staging platform 120 may include a pre-treatment station, a post-treatment station, and stations for different processes (e.g., plasma treatment, annealing, etc.).

The processing platform 20 may include a second rotary track mechanism 245 to support and rotate the plurality of the substrates 210 transferred thereon at a second rotating speed (e.g., from zero to less than 30 rpm). After being prepared and processed within the staging platform 120, the substrates 210 can be transferred from the staging platform 120 to the processing platform 200, for example, via the exchange and connections of the tracks of the first rotary track mechanism 247 and the second rotary track mechanism 245 (similar to the track exchange of railroad tracks. In one aspect, to facilitate substrate transfer, the first rotating speed of the first rotary track mechanism 247 is matched to be about the same speed as the second rotating speed of the second rotator track mechanism 245.

During substrate processing, the second rotary track mechanism 245 is configured to rotate in a direction 242 (e.g., clockwise or counterclockwise) such that the plurality of substrates 210 (whether disposed on the plurality of substrate carriers 240 or directly disposed on the second rotary track mechanism 245) are rotated under and passed through one or more gas distribution assemblies 250. In one or more embodiments, each substrate carrier disposed on each rotary track mechanism is capable of self-rotating at a third rotating speed (e.g., from zero to less than 30 rpm).

The processing platform 200 is adapted to simultaneously process multiple substrates by rotating each of the plurality of the substrates 210 under one or more shower head stations 250 positioned at a distance above the rotary second track mechanism 245. Each shower head station 250 includes a gas distribution assembly 252. By rotating the plurality of the substrates 210 and passed them through multiple gas distribution assemblies 250, each substrate 210 is sequentially exposing to two or more process gases delivered from the gas distribution assemblies 252. Each gas distribution assembly 252 is configured to alternatingly deliver different types of process gases (e.g., reactive precursor gasses, inert gases and other fluids or compounds). In general, the second rotary track mechanism 245 is at a distance below the plane of the gas distribution assembly 252 of the shower head station 250.

FIG. 4B is a schematic plan view of another example of the substrate processing system 100 configured with the staging platform 120 and the processing platform 200, and capable of continuously loading, unloading and processing multiple substrates in accordance with another embodiment of the invention.

The staging platform 120 may include a substrate support assembly 277 (e.g., a carousel-like mechanism), which is capable of rotationally movement in a horizontal direction 246 (e.g., clockwise or counter-clockwise). The substrate support assembly 277 may include a multi-substrate receiving surface capable of supporting multiple substrates 210 or multiple substrate carriers 240 with the substrates 210 disposed thereon. The substrate support assembly 277 is configured to be supported and rotated (e.g., by a rotating shaft or the first rotary track mechanism 247). Each substrate 210 may be disposed directly on specific locations on the receiving surface of the substrate support assembly 277. Alternatively, each substrate 210 may be supported by a substrate carrier 240 for ease of securing each substrate 210 on the substrate support assembly 277.

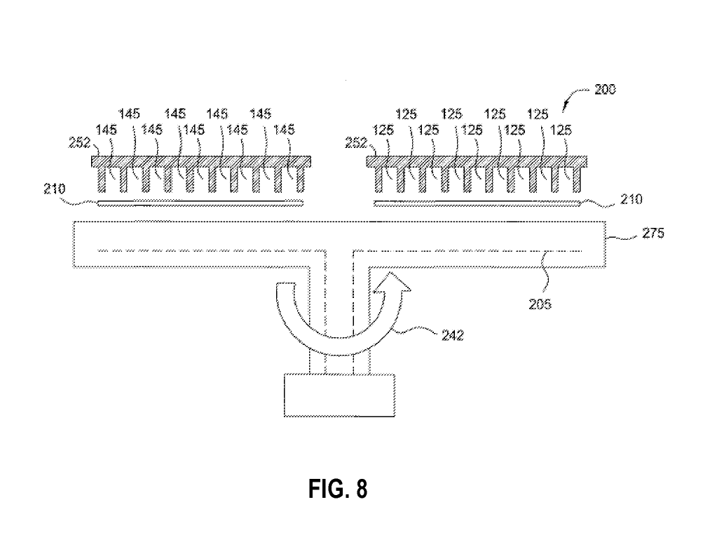

The processing platform 200 may include a substrate support assembly 275 (e.g., a carousel-like mechanism) which is capable of rotationally movement in a horizontal direction 242 (e.g., clockwise or counter-clockwise). The substrate support assembly 275 may include a multi-substrate receiving surface capable of supporting multiple substrates 210 or multiple substrate carriers 240 with the substrates 210 disposed thereon. The substrate support assembly 275 is configured to be supported and rotated (e.g., by a rotating shaft as shown in FIG. 8 or the first rotary track mechanism 245).). Each substrate 210 may be disposed directly on specific locations on the receiving surface of the substrate support assembly 275. Alternatively, each substrate 210 may be supported by a substrate carrier 240 for ease of securing each substrate 210 on the substrate support assembly 275.

As noted above, system throughput is substantially improved by performing the most time-consuming elements of substrate transfer (e.g., substrate loading and unloading, load lock pumping and venting, etc.) while the substrates are processed. The configuration illustrated in FIGS. 4A and 4B may reduce or eliminate the contribution of these factors and improve system throughput.

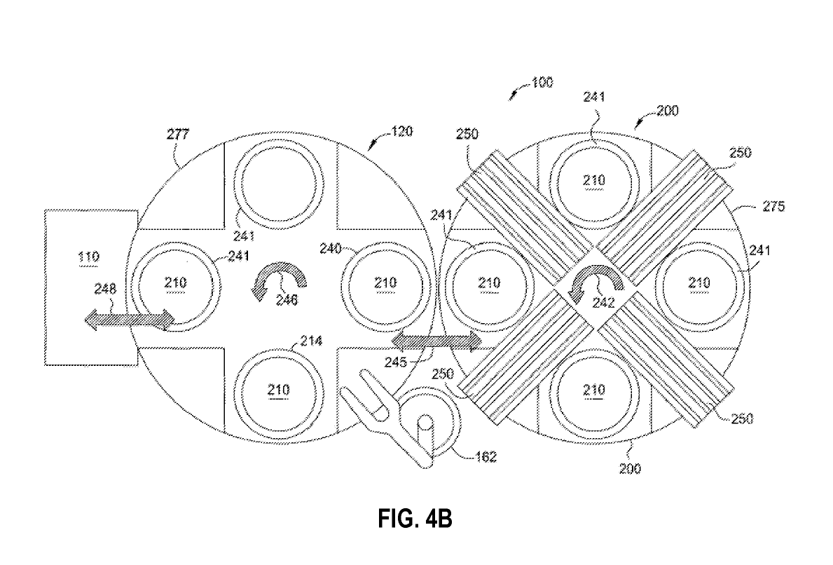

FIG. 5 is a schematic plan view of the processing platform 200 with multiple shower head stations 250. Optionally multiple buffer stations 248 are disposed in-between the shower head stations for spatially separating each shower head station 250 and/or conducting substrate heating or curing of the films deposited over the surface of the substrates 210.

As shown in FIG. 5, a plurality of the substrates 210 can be rotationally disposed below the gas distribution assemblies 252 of the multiple shower head stations 250. During substrate processing, the rotary track mechanism 245 or the shaft below the substrate support assembly 275 is configured to rotate in the horizontal direction 242 (e.g., clockwise or counterclockwise) at a first rotating speed (e.g., from zero to less than 30 rpm) such that the plurality of substrates 210 are rotated under and passed through each of the shower head stations 250 and the buffer stations 248.

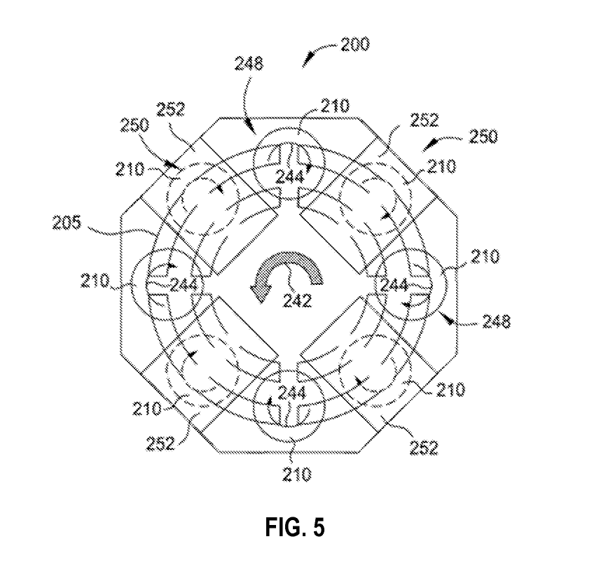

FIG. 6 illustrates a side view of the gas distribution assembly 252 in a shower head station 250, the side facing the surface of the substrate 210. FIG. 7 is a partial cross-sectional side view of the gas distribution assembly 252 with the substrate 210 disposed below.

The gas distribution assembly 252 may include multiple gas channels 125, 135, 145, with multiple openings facing the surface of the substrate 210 for delivery of precursor gas A, precursor gas B, and purge gas, from gas boxes 120, 130, 140, respectively. Multiple gas channels 155 are connected to a pumping system and provided for pumping excess gasses out of the processing space above the surface of the substrate 210. In one or more embodiments, the gas channels 125, 135, 145, 155 are spatially separated and alternatively disposed across a horizontal plane of the gas distribution assembly 252. In another embodiment, precursor gas A, precursor gas B, and purge gas are continuously flown into the gas channels 125, 135, 145, 155 and onto different locations over the surface of the substrate 210.

Each gas channel 125, 135 is provided for delivery of a gas flow a precursor compound from to be chemi-absorbed over the surface of the substrate 210 when the substrate is rotated and arrived below each gas channel 125, 135. Each gas channel 145 is provided for delivery of a gas flow of a purge gas to separate each flow of the precursor A and precursor B over the surface of the substrate 210 when the substrate is rotated and arrived below the gas channel 145. Accordingly, each substrate 210 may be exposed to precursor gas A, precursor gas B, and purge gas simultaneously, but at different locations, when disposed under the openings of the multiple gas channels 125, 135, 145, which are spatially separated within each gas distribution assembly 252.

FIG. 8 is a partial cross-sectional side view of the processing platform 200, showing two substrates 210 disposed below two gas distribution assemblies 252 of two processing stations 250 on the surface of a rotary substrate support assembly 275. As shown in FIG. 8, a portion of a substrate may be exposed to multiple flows of precursor gas A via the openings of the gas channel 125, while a portion of another substrate may be exposed to multiple flows of purge gas via the openings of the gas channel 145.

In addition, the process temperature and pressures within the processing platform 200 are controlled at levels suitable for an ALD or CVD process. For example, one or more pumps may be disposed inside the processing platform 200 and one or more heater system 205 may be disposed below the substrate support assembly 275. Additional heating systems may include radiant or convective heating from top or bottom of the substrate support assembly 275. In addition, the processing platform can be coupled to local or remote plasma source for conducting plasma enhanced atomic layer deposition (PEALD) process within the processing system 100.

In operation, for depositing a tantalum nitride (TaN) material layer over a surface of the substrate 210, two precursor compounds may be used. The first precursor may be a tantalum containing compound, such as a tantalum based organo-metallic precursor or a derivative thereof, e.g., pentadimethylamino-tantalum (PDMAT; Ta(NMe₂)₅), pentaethylmethylamino-tantalum (PEMAT; Ta[N(C₂H₅CH₃)₂]₅), pentadiethylamino-tantalum (PDEAT; Ta(NEt₂)s,), TBTDET (Ta(NEt₂)₃NC₄H₉ or C₁₆H₃₉N₄Ta) and tantalum halides, and any and all of derivatives of the above listed compounds. The tantalum containing compound may be provided as a gas or may be provided with the aid of a carrier gas. Examples of carrier gases which may be used include, but are not limited to, helium (He), argon (Ar), nitrogen (N₂), and hydrogen (H₂).

After the delivery of the first precursor gas (precursor gas A) into the processing region 280 of the batch processing chamber 200, a monolayer of the tantalum containing compound is chemisorbed onto the surface of the substrate 210 and excess tantalum containing compound is removed from the process chamber by introducing a pulse of a purge gas thereto. Examples of purge gases which may be used include, but are not limited to, helium (He), argon (Ar), nitrogen (N₂), hydrogen (H₂), and other gases.

After the process chamber has been purged, a second precursor gas (precursor gas B) may be delivered into the processing regions 280 of the batch processing chamber 200. The second precursor may be a nitrogen containing compound with nitrogen atoms and one or more reactive atoms/species. For example, the nitrogen containing compound may be ammonia gas (NH3) and other nitrogen containing compounds, including, but not limited to, NₓH_{y} with x and y being integers (e.g., hydrazine (N₂H₄)), dimethyl hydrazine ((CH₃)₂N₂H₂), t-butylhydrazine (C₄H₉N₂H₃) phenylhydrazine (C₆H₅N₂H₃), other hydrazine derivatives, a nitrogen plasma source (e.g., N₂, N₂/H₂, NH₃, or a N₂H₄ plasma), 2,2′-azoisobutane ((CH₃)₆C₂N₂), ethylazide (C₂H₅N₃), and other suitable gases. The nitrogen containing compound may be introduced into the processing region 280 as a pulse, and may be provided alone. Alternatively, a carrier gas may be used to deliver the nitrogen containing compound if necessary.

After the delivery of the second precursor gas (precursor gas A) into the processing region 280 of the batch processing chamber 200, a monolayer of the nitrogen containing compound may then be chemisorbed on the monolayer of the tantalum containing compound. The composition and structure of precursors on a surface during atomic-layer deposition (ALD) is not precisely known. Not wishing to be bound by theory, it is believed that the chemisorbed monolayer of the nitrogen containing compound reacts with the monolayer of the tantalum containing compound to form a tantalum nitride layer. Reactive species from the two precursor compounds may form by-products that are transported from the substrate surface (e.g., via the fluid outlets 262 and the exhaust system 260). It is believed that the reaction of the nitrogen containing compound with the tantalum containing compound is self-limiting and, in each pulse of delivering a precursor compound into the processing region 280, only one monolayer of the precursor compound is chemisorbed onto the surface of the substrate 210. Each cycle of the sequential delivery of the two or more alternating precursors over the surface of the substrate is repeated (e.g., 20-30 cycles) until a desired thickness of the material layer (e.g., a tantalum nitride film) is formed.

A fluid delivery system may be in fluid communication with the internal process volume below each of the gas distribution assemblies 250 and may be positioned in a facilities tower proximate the processing platform 200. A system controller is connected to the processing platform 200 and/or the multi-chamber substrate processing system 100 for controlling the process performed inside the processing platform 200.

One method processing a substrate within the substrate processing system 100 includes loading a substrate onto a substrate carrier being rotated. by a first rotary track mechanism of a staging platform of the substrate processing system, rotating the first rotary track mechanism at a first rotating speed, loading the substrate carrier having the substrate thereon onto a second rotary track mechanism of a processing platform of the substrate processing system, rotating the second rotary track mechanism at a second rotating speed such that the substrate is moved under and passed through one or more gas distribution assemblies positioned at a first distance above the second rotary track mechanism, and unloading the substrate carrier from the second rotary track mechanism onto the first rotary track mechanism of the batch processing platform.

Another method for processing a substrate within a substrate processing system includes loading the substrate onto a first substrate support assembly, which is being rotated by a first rotary track mechanism disposed within a staging platform of the substrate processing system, rotating the first rotary track mechanism at a first rotating speed, loading the substrate carrier having the substrate thereon onto a second substrate support assembly, which is being rotated by a second rotary track mechanism disposed within a processing platform of the substrate processing system, rotating the second rotary track mechanism at a second rotating speed such that the substrate is moved under and passed through one or more gas distribution assemblies positioned at a first distance above the second rotary track mechanism, and unloading the substrate carrier from the second substrate support assembly, of the processing platform onto the first substrate support assembly of the staging platform.

While the foregoing is directed to embodiments of the present invention, other and further embodiments of the invention may be devised without departing from the basic scope thereof, and the scope thereof is determined by the claims that follow.

What is claimed is:

1. A processing chamber comprising:
a plurality of gas distribution assemblies spaced about the processing chamber;
a substrate support apparatus within the processing chamber, the substrate support apparatus to rotate to carry substrates beneath each of the plurality of gas distribution assemblies; and
a set of first treatment stations between each of the plurality of gas distribution assemblies, each of the first treatment stations providing the same type of treatment.

2. The processing chamber of claim 1, wherein each of the first treatment stations comprises a plasma treatment station.

3. The processing chamber of claim 1, further comprising a set of second treatment stations, each of the second treatment stations positioned between a gas distribution assembly and a first treatment station, so a first treatment station is between a gas distribution assembly and a second treatment station and a second treatment station is between a first treatment station and an adjacent gas distribution assembly.

4. The processing chamber of claim 1, wherein each of the gas distribution assemblies sequentially provides a first reactive gas and second reactive gas to a substrate surface to deposit a film on the substrate surface.

5. The processing chamber of claim 1, wherein the substrate support apparatus comprises a plurality of rotatable substrate carriers, the rotatable substrate carriers rotatable at a different speed and directions from the rotation of the substrate support apparatus.

6. A substrate processing platform for processing a plurality of substrates, the substrate processing platform comprising:
one or more gas distribution assemblies; and
a rotary track to move a plurality of substrates carriers positioned at a distance below the one or more gas distribution assemblies, each substrate carrier to carry at least one substrate thereon and to be rotationally moved by the rotary track at a first rotating speed such that a plurality of substrates disposed on the plurality of substrate carriers are rotated under and passed through the one or more gas distribution assemblies.

7. The substrate processing platform of claim 6, wherein each substrate carrier is self-rotating at a second rotating speed.

8. The substrate processing platform of claim 6, further comprising a substrate support assembly to support the plurality of substrate carriers thereon and being rotated by the rotary track mechanism.

9. A substrate processing system for processing a plurality of substrates, comprising:
a staging platform comprising a first rotary track mechanism, which is capable of receiving a plurality of substrate carriers thereon, wherein each substrate carrier is adapted to carry at least one substrate thereon and to be rotationally moved by the first rotary track mechanism at a first rotating speed; and
the substrate processing platform of claim 6.

10. The substrate processing system of claim 9, wherein the first rotating speed is the same as the second rotating speed.

11. The substrate processing system of claim 9, wherein each substrate carrier disposed on the second rotary track mechanism is capable of self-rotating at a third rotating speed.

12. The substrate processing system of claim 9, further comprising a transfer robot to transfer a substrate from the staging platform to the processing platform.

13. The substrate processing system of claim 9, further comprising a first substrate support assembly to support the plurality of substrate carriers thereon and being rotated by the first rotary track mechanism.

14. The substrate processing system of claim 13, further comprising a second substrate support assembly to support the plurality of substrate carriers thereon and being rotated by the second rotary track mechanism.

15. A substrate processing system for processing a plurality of substrates, comprising:
a staging platform, comprising:
a first substrate support assembly having a first multi-substrate receiving surface capable of receiving the plurality of the substrates thereon; and
a first rotary track mechanism disposed below the first substrate support assembly for rotating the substrate support assembly at a first rotating speed;
a processing platform, comprising:
a second substrate support assembly having a second multi-substrate receiving surface capable of receiving the plurality of the substrates thereon;
one or more gas distribution assemblies disposed at a first distance above the second substrate support assembly; and
a second rotary track mechanism disposed below the second substrate support assembly and capable of rotationally moving the second substrate support assembly at a second rotating speed such that the plurality of substrates disposed on the second substrate receiving surface are passed under the one or more gas distribution assemblies.

16. The substrate processing system of claim 15, wherein the first rotating speed is the same as the second rotating speed.

17. The substrate processing system of claim 15, wherein each substrate carrier disposed on the second rotary track mechanism is capable of self-rotating at a third rotating speed.

18. The substrate processing system of claim 15, further comprising a transfer robot or other mechanism to transfer a substrate from the staging platform to the processing platform.

19. The substrate processing system of claim 15, wherein the gas distribution assemblies comprises a plurality of spatially separated gas channels.
